(19) United States
(12) Patent Application Publication
(10) Pub. No.: US 2026/0011573 A1
(43) Pub. Date: Jan. 8, 2026

(54) SEMICONDUCTOR DEVICE AND FORMATION METHOD THEREOF

(71) Applicants: TAIWAN SEMICONDUCTOR MANUFACTURING COMPANY, LTD., Hsinchu (TW); NATIONAL CHENG KUNG UNIVERSITY, Tainan City (TW)

(72) Inventors: Chao-Ching CHENG, Hsinchu City (TW); Wen-Hsi LEE, Kaohsiung City (TW); Shih-Syun CHEN, Kaohsiung City (TW)

(73) Assignees: TAIWAN SEMICONDUCTOR MANUFACTURING COMPANY, LTD., Hsinchu (TW); NATIONAL CHENG KUNG UNIVERSITY, Tainan City (TW)

(21) Appl. No.: 18/765,139

(22) Filed: Jul. 5, 2024

(51) Int. Cl. H01L 21/443; H01L 21/027; H01L 29/24; H01L 29/45; H01L 29/66; H01L 29/76

(52) U.S. Cl. CPC H01L 21/443; H01L 21/0272; H10D 48/362; H10D 62/80; H10D 64/62; H10D 99/00

(57) ABSTRACT

A method of forming a semiconductor device comprises the following steps. A dielectric layer is formed over a substrate. Source/drain contact layers are formed in the dielectric layer. A 2D material layer is formed over the dielectric layer and the source/drain contact layers. An annealing process is performed to the 2D material layer. After performing the annealing process, a tellurization process is performed to the 2D material layer. A gate structure is formed over the 2D material layer.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5 and 6A are cross-sectional views of a semiconductor device in various stages of fabrication in accordance with some embodiments of the present disclosure.

FIG. 6B shows a Raman spectrum of the first Te-containing layer in accordance with some embodiments.

FIG. 6C shows a Raman spectrum of the second Te-containing layer in accordance with some embodiments.

FIG. 7 is a perspective view of the semiconductor device in various stages of fabrication in accordance with some embodiments of the present disclosure.

FIGS. 8-15 are cross-sectional views of a semiconductor device in various stages of fabrication in accordance with some embodiments of the present disclosure.

FIGS. 16-19 are cross-sectional views of a semiconductor device in various stages of fabrication in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

Post-process is one of the main challenges of 2 dimensional (2D) material processing. For example, source and drain contacts are fabricated after the fabrication process of 2D material channel. The two main methods of forming the source and drain contacts are evaporation and transferring. However, the evaporation causes serious damage to the 2D material channel. The transferring technology has not yet emerged as a definite solution in terms of application to complex 3D structures and uniformity. In fin field effect transistor (FET) fabrication process sequence, some damage caused by a metallization process to the channel would adversely affect a quality of an ohmic contact.

Embodiments of the present disclosure provide a method of forming an ohmic contact between a 2D material channel and a source/drain contact without using a destructive process, and thus a quality of the 2D material channel can be maintained.

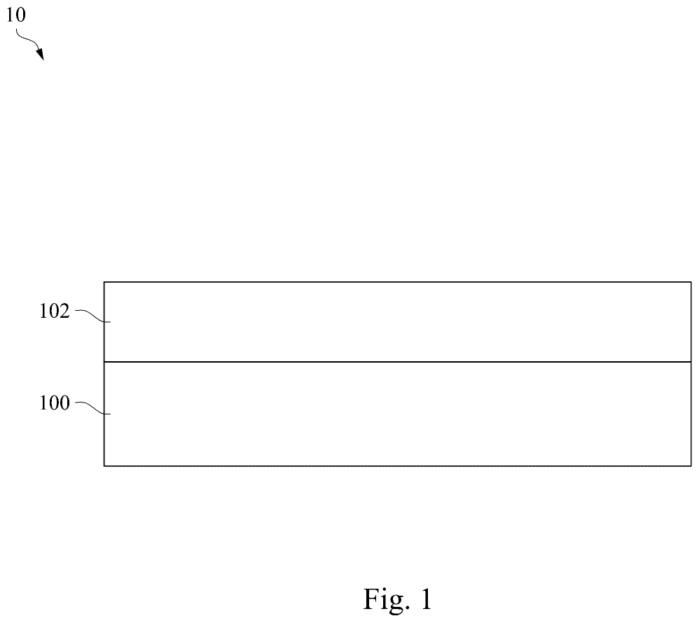

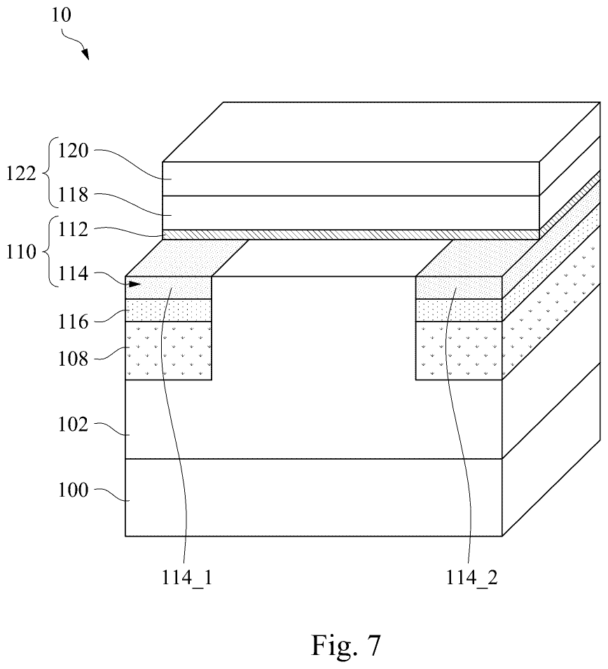

FIGS. 1, 2, 3, 4, 5 and 6A are cross-sectional views of a semiconductor device 10 in various stages of fabrication in accordance with some embodiments of the present disclosure. FIG. 7 is a perspective view of the semiconductor device 10 in various stages of fabrication in accordance with some embodiments of the present disclosure. Reference is made to FIG. 1. The substrate 100 illustrated in FIG. 1 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. In some embodiments, the substrate 100 is a silicon substrate doped with p-type dopants. Other substrates that may be used include multi-layered substrates, gradient substrates, or hybrid orientation substrates.

In some embodiments, a dielectric layer 102 is formed over the substrate 100. Before forming the dielectric layer 102, a clean process may be performed to the substrate 100. For example, the cleaning process may be performed using chemicals such as sulfuric acid, ammonia water, hydrofluoric acid, or the like. In some embodiments, the dielectric layer 102 is an oxide layer, such as silicon dioxide, formed by oxidizing the substrate 100, such as a silicon substrate by, for example, thermal oxidation, plasma oxidation, or high pressure oxidation. In some other embodiments, the dielectric layer 102 may be other materials including SiON, SiCN or SiOCN, SiN formed using chemical vapor deposition (CVD), physical vapor deposition (PVD), atomic layer deposition (ALD), or other suitable process.

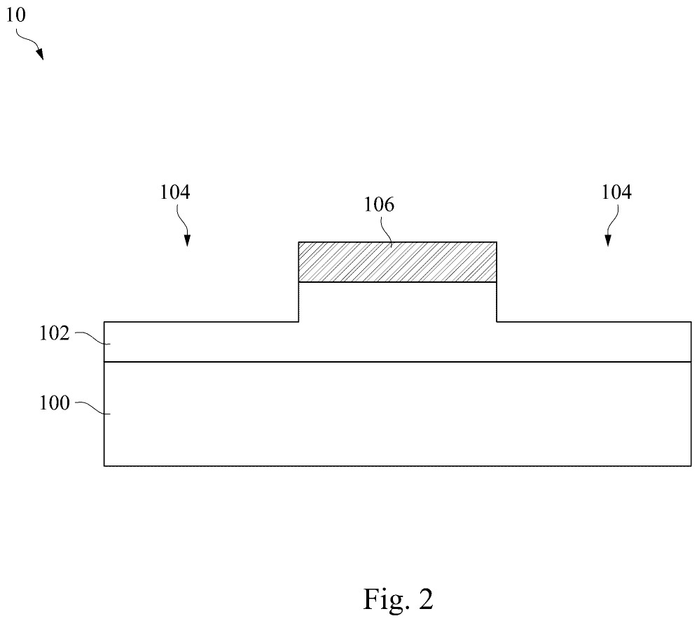

Reference is made to FIG. 2. In some embodiments, the dielectric layer 102 is patterned, forming trenches 104 in the dielectric layer 102, using, for example, a photolithography process. An exemplary photolithography process includes coating a resist layer (or photoresist layer) 106 over the dielectric layer 102, soft baking the resist layer 106, and exposing the resist layer 106 using a mask. The photolithography process further includes post-exposure baking (PEB), developing, and hard baking thereby removing unexposed portions or exposed portions of the resist layer 106 over the dielectric layer 102. The dielectric layer 102 is etched using the resist layer 106 as a mask to form the trenches 104. In an embodiment, a remaining portion of the resist layer 106 is also removed during etching the dielectric layer 102. In some embodiments, the resist layer 106 is removed by an ashing operation such as a plasma ash.

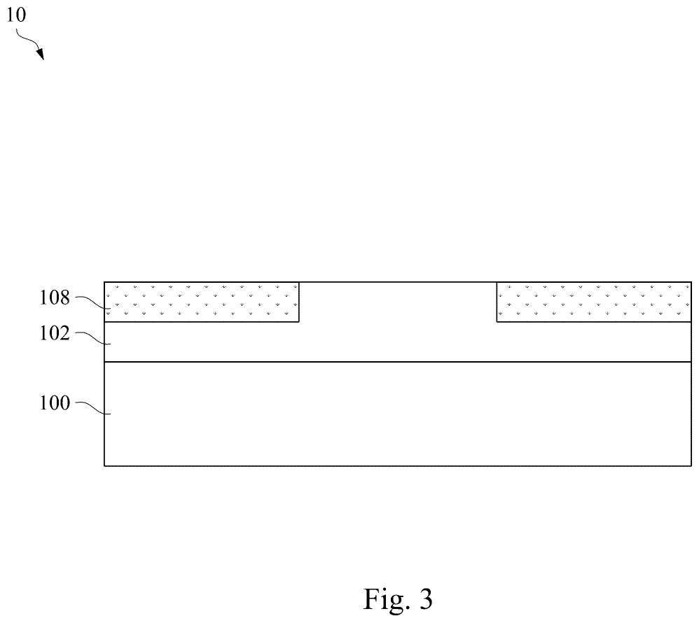

Reference is made to FIG. 3. In some embodiments, source/drain contact layers 108 are formed in the trenches 104. Formation of the source/drain contact layers 108 includes a deposition process to fill the trenches 104 with a conductive material followed by polishing (such as chemical mechanical polishing) to remove an excessive portion of the conductive material and to planarize a top surface of the dielectric layer 102. In some embodiments, the source/drain contact layers 108 include one or more metal layers including aluminum (Al), tungsten (W), copper (Cu), cobalt (Co), or other suitable materials, and may be formed by CVD, PVD, plating, or other suitable processes.

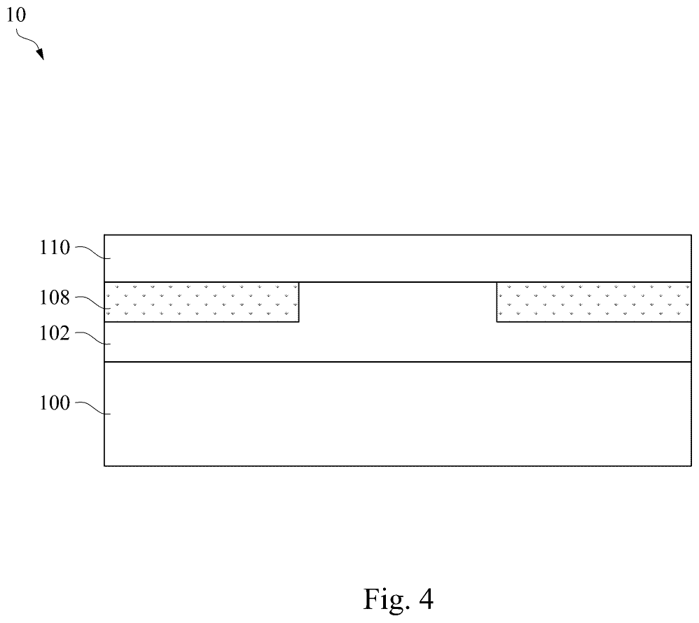

Reference is made to FIG. 4. In some embodiments, a 2D material layer 110 is formed over the dielectric layer 102 and the source/drain contact layers 108. As used herein, consistent with the accepted definition within solid state material art, a “2D material” may refer to a crystalline material consisting of a single layer of atoms. As widely accepted in the art, “2D material” may also be referred to as a “monolayer” material. In this disclosure, “2D material” and “monolayer” material are used interchangeably without differentiation in meanings, unless specifically pointed out otherwise.

In some embodiments, the 2D material layer 110 may be a 2D semiconductor layer. For example, the 2D material layer 110 may include transition metal oxide, such as molybdenum (Mo) oxide. In other words, the 2D material layer 110 is a transition metal oxide layer. In a 2D form, the molybdenum (Mo) oxide is a layered Van der Waals (vdW) semiconductor in a layered structure with a plurality of two-dimensional layers of the general form X-M-X, with the oxygen atoms in two planes separated by a plane of metal atoms. The 2D material layer 110 can be a mono-layer or may include a few mono-layers. The Mo oxide has high electrical conductivity and is a thermodynamically stable layered semiconductor material. In a 2D form, a large number of atoms of Mo oxide are exposed due to large area-to-volume ratio, which enhances the reaction sites.

In some embodiments, the 2D material layer 110 is formed by physical vapor deposition (PVD) such as pulsed laser deposition (PLD), sputtering deposition, thermal evaporation, cathodic arc deposition, or other suitable deposition methods. Fabrication of PVD can be carried out in a high vacuum circumstance, inside which a target material with condensed state is transformed to vapor phase and then converted to thin film state.

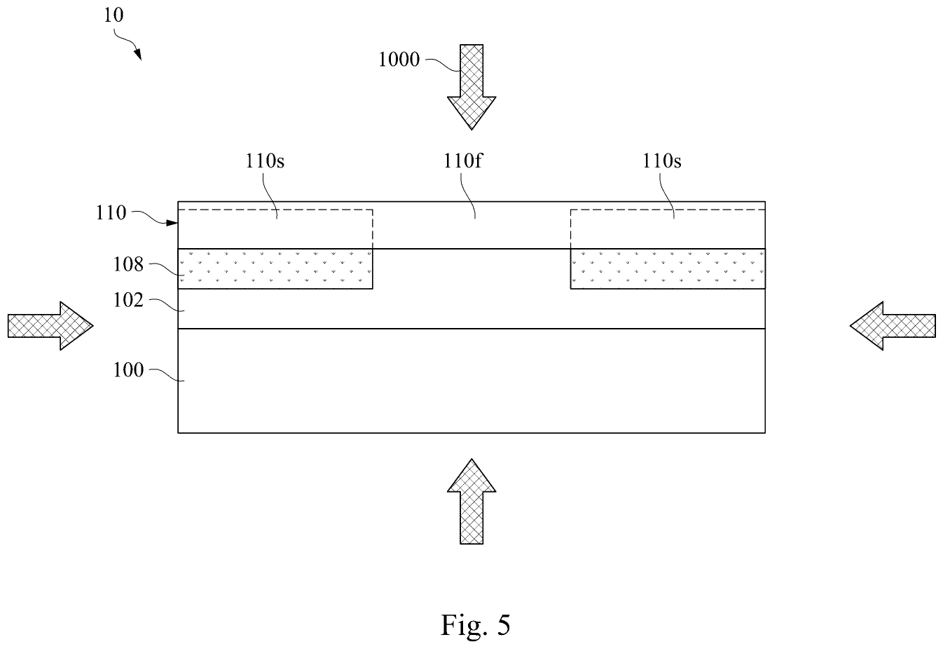

Reference is made to FIG. 5. In some embodiments, a pre-treatment process 1000 is performed to the 2D material layer 110 to control a phase of a subsequently formed 2D material layer. For example, the pre-treatment process 1000 is a high pressure annealing (HPA) process performed using oxygen, nitrogen, or a combination thereof. The substrate 100, having the 2D material layer 110 thereon, may be transferred to an anneal chamber. The temperature and pressure within the anneal chamber is raised to a predetermined temperature and a predetermined pressure in order to perform the HPA. The increased temperature and pressure forces the oxygen, nitrogen, or a combination thereof within the anneal chamber to penetrate into the 2D material layer. In other words, during the HPA, the oxygen, nitrogen, or a combination thereof, are carried into the 2D material layer by the high pressure. The 2D material layer 110 can be treated with the HPA for a desired soak time.

In some embodiments, the 2D material layer 110 has a first portion 110f proximate to the source/drain contact layers 108 and a second portion 110s distant from the source/drain contact layers 108. In other words, the second portion 110s is closer to the source/drain contact layers 108 than the first portion 110f is. The first portion 110f can be referred to as being treated directly in the pre-treatment process 1000. The second portion 110s can be referred to as being treated indirectly in the pre-treatment process 1000. Due to the first portion 110f being treated directly and the second portion 110s being treated indirectly in the pre-treatment process 1000, the first portion 110f and the second portion 110s would turn into different phases in a subsequent tellurization process, which will be discussed in greater detail below.

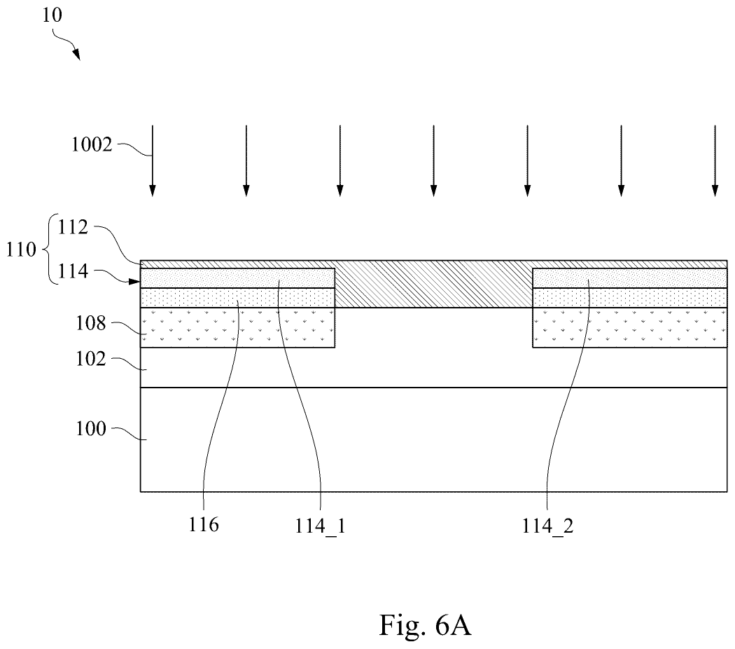

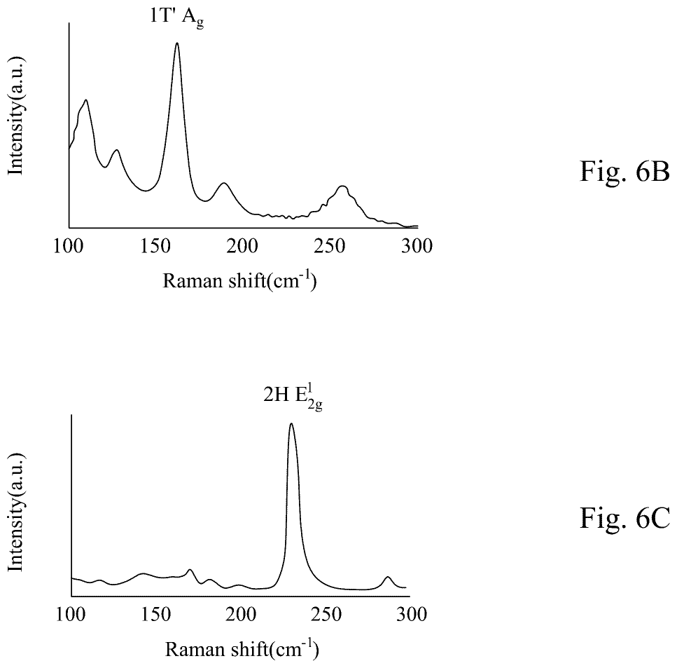

Reference is made to FIG. 6A. In some embodiments, a tellurization process 1002 is performed to the 2D material layer 110 using suitable methods, such as suing chemical vapor deposition (CVD). For example, the 2D material layer 110 and tellurium powers are disposed in a CVD reactor. Carrier gases may then be introduced into the CVD reactor as carrier gas to transport the Te vapor to the 2D material layer 110 ate a suitable temperature. For example, the carrier gases may be inert gas, hydrogen gas, or a combination thereof. In some embodiments, the carrier gas may be a mixture of hydrogen gas and Ar gas.

During the tellurization process 1002, the first portion 110f of the 2D material layer 110 forms a first Te-containing layer 112 with a semiconductor phase while the second portion 110s of the 2D material layer 110 forms a second Te-containing layer 114 with a semimetal phase. For example, the first Te-containing layer 112 include MoTe₂ with 2H phase (hexagonal structure), which is a semiconductor phase, and the second Te-containing layer 114 include MoTe₂ with 1T′ phase (distorted octahedral structure), which is a semimetal phase. Therefore, the first Te-containing layer 112 and the second Te-containing layer 114 form an MoTe₂ heterophase junction after the tellurization process 1002. The phases of the first Te-containing layer 112 and the second Te-containing layer 114 can be characterized using Raman spectroscopy. FIG. 6B shows a Raman spectrum of the first Te-containing layer 112 in accordance with some embodiments. FIG. 6C shows a Raman spectrum of the second Te-containing layer 114 in accordance with some embodiments. As evident from the Raman spectrum in FIG. 6B, the presence of peak between cm-1 and cm-1 can be assigned to the Ag

The Raman spectrum shown in FIG. 6B may, as an example, be obtained by performing Raman spectroscopy on the first Te-containing layer 112, which is formed after the tellurization process 1002 is complete. As shown in FIG. 6B, the existence of the first Te-containing layer 112 with 1T′ phase is confirmed by a first characteristic peak Ag corresponding to out-of-plane vibration of atoms. In the Raman spectrum shown in FIG. 6B, the first characteristic peak Ag is located in a range from about 150 cm⁻¹ to about 200 cm⁻¹. The Raman spectrum shown in FIG. 6C may, as an example, be obtained by performing Raman spectroscopy on the second Te-containing layer 114, which is formed after the tellurization process 1002 is complete. As shown in FIG. 6C, the existence of the second Te-containing layer 114 with 2H phase is confirmed by a second characteristic peak E¹_{2g} corresponding to in-plane vibration of atoms. In the Raman spectrum shown in FIG. 6C, the second characteristic peak E¹_{2g} is located in a range from about 200 cm⁻¹ to about 250 cm⁻¹.

It is noted that the positions of the first characteristic peak Ag and the second characteristic peak E¹_{2g} for WTe₂ can vary slightly within the above-mentioned ranges depending on the process parameters of the tellurization process 1002.

In FIG. 6A, the second Te-containing layer 114 has two Te-containing portions 114_1, 114_2 laterally separated from each other, and the first Te-containing layer 112 is between the two Te-containing portions 114_1, 114_2. In some embodiments, the 2D material layer 110 and the source/drain contact layers 108 interdiffuse during the tellurization process 1002, forming an alloy region 116 between the second Te-containing layer 114 and the source/drain contact layers 108. For example, the alloy region 116 may be WTe₂. The first Te-containing layer 112 with the semiconductor phase can serve as a channel of a transistor (i.e., the semiconductor device 10). Since the source/drain contact layers 108 are formed before forming the channel (i.e., the first Te-containing layer 112), the fabrication process can be described as a “contact first process.” Since the channel (i.e., the first Te-containing layer 112) and the source/drain contact layers 108 can form an Ohmic contact without using a destructive process, a quality of the 2D material channel (i.e., the first Te-containing layer 112) can be maintained.

Reference is made to FIG. 7. A gate structure 122 is formed over the first Te-containing layer 112. The gate structure 122 may be a high-k/metal gate (HKMG) stack, however, other compositions are possible. The gate structure 122 may be formed by forming a high-k gate dielectric layer 118 and a gate electrode layer 120 over the dielectric layer 102 and the first Te-containing layer 112 in sequence, followed by forming a mask layer (not shown) over the gate electrode layer 120 and patterning the mask layer to expose the gate electrode layer 120. In some embodiments, the mask layer may be a photoresist material formed using a spin-on coating process, followed by patterning the photoresist material using suitable lithography techniques. Details of the lithography techniques for the mask layer is similar to the resist layer 106 as discussed previously with regard to FIG. 2, and thus the description thereof is omitted herein. After the mask layer is formed and patterned, the gate electrode layer 120 is etched using the mask layer as an etch mask, exposing the high-k gate dielectric layer 118. The high-k gate dielectric layer 118 is then etched using the gate electrode layer 120 as an etch mask. The first Te-containing layer 112 is then etched using the high-k gate dielectric layer 118 as an etch mask, exposing the second Te-containing layer 114 and the dielectric layer 102.

The semiconductor device 10 can include additional layers, not shown in FIG. 7. For example, additional back-end-of-line (BEOL) layers, middle-of-line (MOL) layers can be formed over the gate structure 122. By way of example and not limitation, an MOL layer can include a network of contacts that connect transistors and capacitor structures in front end of line (FEOL) to the structures in the BEOL layers.

In some embodiments, the high-k gate dielectric layer 118 has a dielectric constant greater than about 7.0, and may include a metal oxide or a silicate of Hf, Al, Zr, La, Mg, Ba, Ti, or Pb, or combinations thereof. The formation methods of the high-k gate dielectric layer 118 may include Molecular-Beam Deposition (MBD), ALD, plasma-enhanced CVD (PECVD), and the like. The gate electrode layer 120 may include one or more work function layers and a fill metal layer (not separately illustrated). The one or more work function layers can provide a suitable work function for the gate structure 122. For an n-type gate-all-around (GAA) FET, the one or more work function layers may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. On the other hand, for a p-type GAA FET, the one or more work function layers may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal layer may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

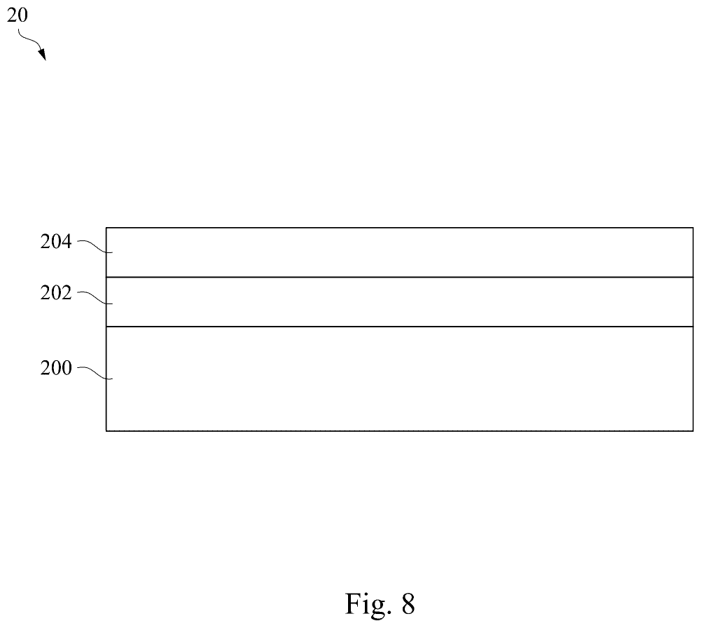

FIGS. 8-13 are cross-sectional views of a semiconductor device 20 in various stages of fabrication in accordance with some embodiments of the present disclosure. Reference is made to FIG. 8. In some embodiments, a dielectric layer 202 and a metal layer 204 are formed over a substrate 200 in sequence. In some embodiments, before forming the dielectric layer 202, a clean process is performed to the substrate 200, as discussed previously with regard to FIG. 1. The substrate 200 and the dielectric layer 202 are similar to the substrate 100 and the dielectric layer 102, respectively, with regard to FIG. 1 in terms of composition and formation method thereof, and thus the description thereof is omitted herein. The metal layer 204 may be a transition metal layer, such as an Mo layer, and can be formed by PVD, CVD, ALD, or the like.

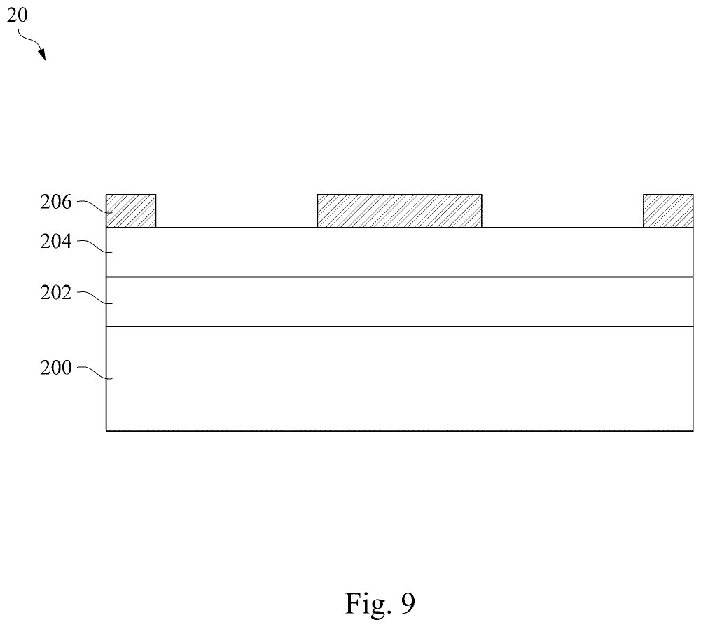

In FIG. 9, a mask layer 206 is formed over the metal layer 204 and then patterned to expose the metal layer 204. In some embodiments, the mask layer 206 may be a photoresist material formed using a spin-on coating process, followed by patterning the photoresist material using suitable lithography techniques. The mask layer 206 can be referred to as a photoresist layer. Details of the lithography techniques for the mask layer 206 is similar to the resist layer 106 as discussed previously with regard to FIG. 2, and thus the description thereof is omitted herein.

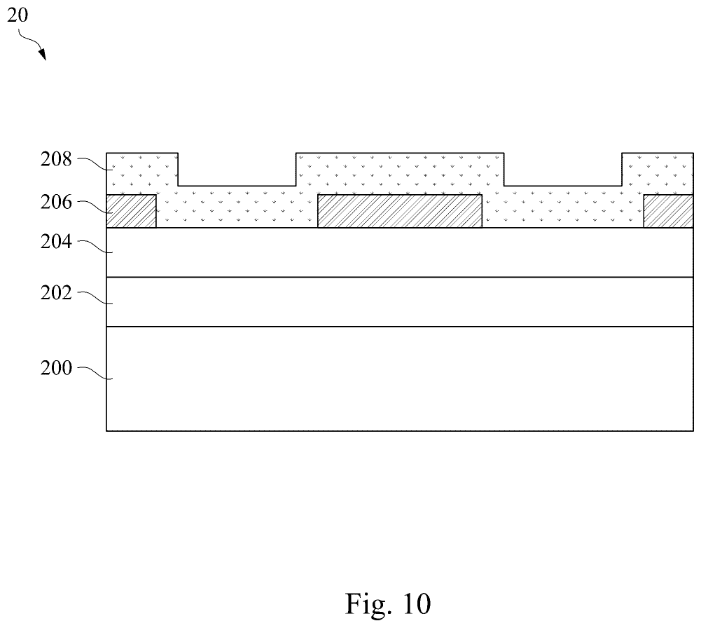

Reference is made to FIG. 10. A conductive layer 208 is formed on the mask layer 206 and the metal layer 204 such as using ALD, CVD, low pressure CVD (LPCVD), PVD, plating, evaporation, ion beam, energy beam, or other suitable deposition methods. In some embodiments, the conductive layer 208 includes metal such as aluminum (Al), copper (Cu), tungsten (W), gold (Au), the like, or a combination thereof. In some embodiments, the conductive layer 208 is conformally formed on the mask layer 206 and the metal layer 204.

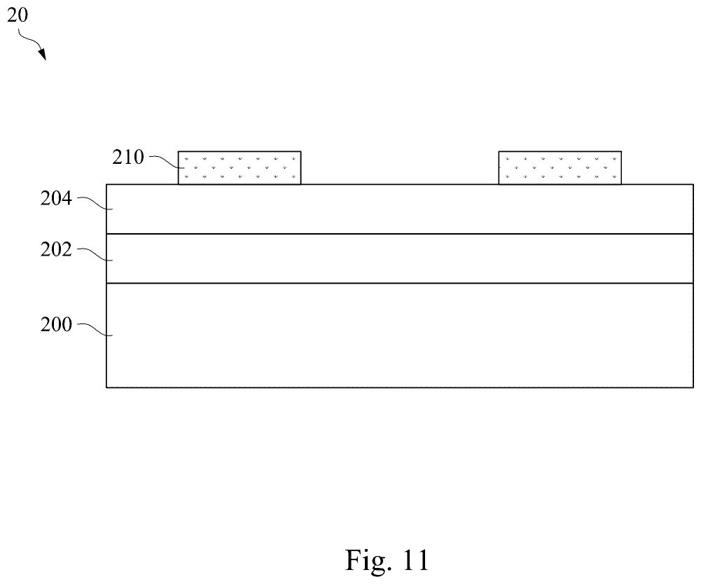

In FIG. 11, the mask layer 206 can be removed by using, for example, a lift-off process. Lifting off the mask layer 206 also removes an overlying portion of the conductive layer 208, thus leaving other portions of the conductive layer 208 on the top surface of the metal layer 204 to serve as source/drain contact layers 210. The metal layer 204 is thus exposed. In other words, the conductive layer 208 is partially removed during lifting off the mask layer 206.

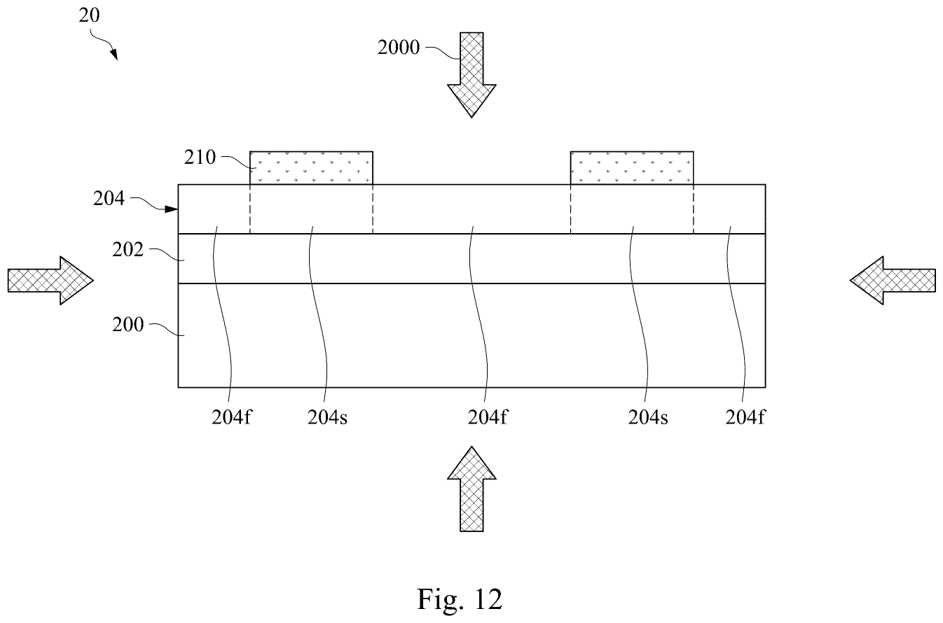

Reference is made to FIG. 12. In some embodiments, a pre-treatment process 2000 is performed to the metal layer 204 to control a phase of a subsequently formed 2D material layer. Since the metal layer 204 has a first portion 204f exposed by the source/drain contact layers 210 and distinct from the source/drain contact layers 210, during the pre-treatment process 2000, the first portion 204f can be referred to as being treated directly in the pre-treatment process 2000. The 2D material layer 206 has a second portion 204s covered by the source/drain contact layers 210 and proximate to the source/drain contact layers 210, and he second portion 204s can be referred to as being treated indirectly in the pre-treatment process 2000. Due to the first portion 204f being treated directly and the second portion 204s being treated indirectly in the pre-treatment process 2000, the first portion 204f and the second portion 204s would turn into different phases in a subsequent tellurization process, which will be discussed in greater detail below. In some embodiments, the pre-treatment process 2000 is a high pressure annealing (HPA) process performed using oxygen, nitrogen, or a combination thereof. Details of the pre-treatment process 2000 is similar to the pre-treatment process 1000 as discussed previously with regard to FIG. 5, and thus the description thereof is omitted herein.

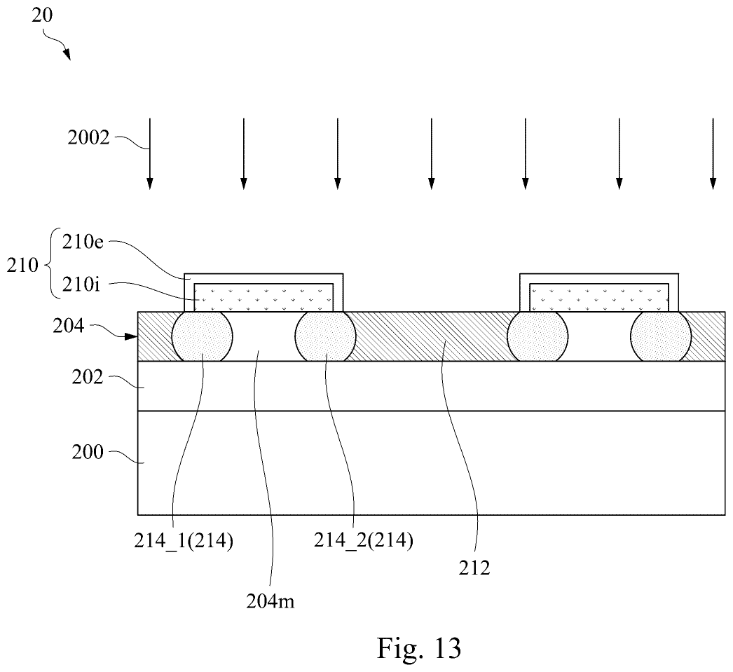

Reference is made to FIG. 13. In some embodiments, a tellurization process 2002 is performed to the metal layer 204 using suitable methods, such as suing CVD. Details of the tellurization process 2002 is similar to the tellurization process 1002 as discussed previously with regard to FIG. 6A, and thus the description thereof is omitted herein. During the tellurization process 2002, the first portion 204f of the metal layer 204 forms a first Te-containing layer 212 with a semiconductor phase while side regions of the second portion 204s of the metal layer 204 form a second Te-containing layer 214 with a semimetal phase. For example, the first Te-containing layer 212 include MoTe₂ with 2H phase (hexagonal structure), which is a semiconductor phase, and the second Te-containing layer 214 include MoTe₂ with 1T′ phase (distorted octahedral structure), which is a semimetal phase. The first Te-containing layer 212 and the second Te-containing layer 214 form an MoTe₂ heterophase junction after the tellurization process 2002. The metal layer 204 may have a metal portion 204m being not tellurized during the tellurization process 2002 and thus remain including Mo. The metal portion 204m c may be in the middle region of the metal layer 204. In other words, the metal portion 204m is free from Te. In some embodiments, the second Te-containing layer 214 has two Te-containing portions 214_1, 214_2 laterally separated from each other, and the metal portion is on opposite sidewalls of the metal portion 204m of the metal layer 204.

In some embodiments, an exterior region 210e of the source/drain contact layer 210 can be tellurized during the tellurization process 2002, forming an alloy including WTe₂ while an interior region 210i of the source/drain contact layer 210 may not be tellurized and remain including W.

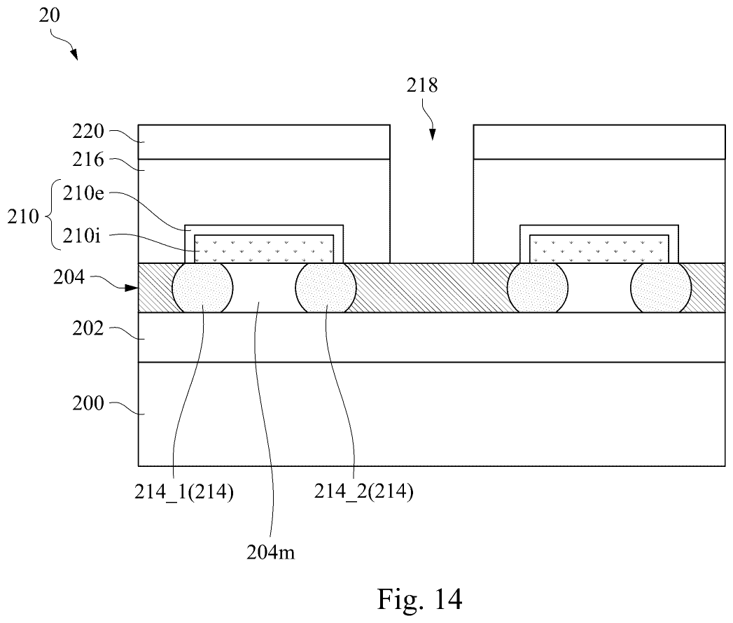

Reference is made to FIG. 14. An interlayer dielectric (ILD) layer 216 is formed over the metal layer 204 and the source/drain contact layer 210. In some embodiments, the ILD layer 216 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), or the like. The ILD layer 216 may be deposited by a PECVD process or other suitable deposition technique. In some embodiments, after formation of the ILD layer 216, the substrate 200 may be subject to a high thermal budget process to anneal the ILD layer 216. In some examples, after forming the ILD layer 216, a planarization process may be performed to remove excessive materials of the ILD layer 216. For example, a planarization process includes a chemical mechanical polishing (CMP) process which removes portions of the ILD layer 216.

The ILD layer 216 is then patterned, forming a gate trench 218, using, for example, a photolithography process. An exemplary photolithography process includes coating a resist layer 220 over the ILD layer 216, soft baking the resist layer 220, and exposing the resist layer 220 using a mask. The photolithography process further includes post-exposure baking (PEB), developing, and hard baking thereby removing unexposed portions or exposed portions of the resist layer 220 over the ILD layer 216. The ILD layer 216 is etched using the resist layer 220 as a mask to form the gate trench 218. In an embodiment, any remaining portion of the resist layer 220 is also removed during etching the ILD layer 216.

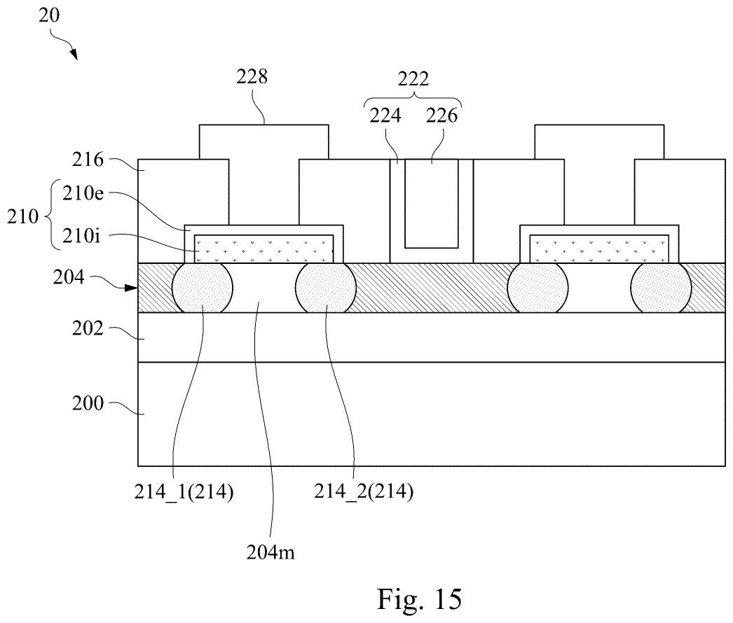

Reference is made to FIG. 15. Thereafter, a gate structure 222 is formed in the gate trench 218. The gate structure 222 may be a high-k/metal gate (HKMG) stack, however, other compositions are possible. In various embodiments, the gate structure 222 includes a high-k gate dielectric layer 224 lining the gate trench 218 and a gate electrode layer 226 formed over the high-k gate dielectric layer 224 and filling a remainder of gate trench 218. The high-k gate dielectric layer 224 and the gate electrode layer 226 are similar to the high-k gate dielectric layer 118 and the gate electrode layer 120 as discussed previously with regard to FIG. 7 in terms of composition and formation method, and thus the description thereof is omitted herein.

In some embodiments, the ILD layer 216 is then patterned to form openings on the source/drain contact layers 210 to expose the source/drain contact layers 210, using, for example, a photolithography process. Thereafter, a conductive material 228 is formed in the openings. The conductive material 228 may include a material similar to the material of the source/drain contact layers 210.

The semiconductor device 20 can include additional layers, not shown in FIG. 15. For example, additional back-end-of-line (BEOL) layers, middle-of-line (MOL) layers can be formed over the gate structure 222. By way of example and not limitation, an MOL layer can include a network of contacts that connect transistors and capacitor structures in front end of line (FEOL) to the structures in the BEOL layers.

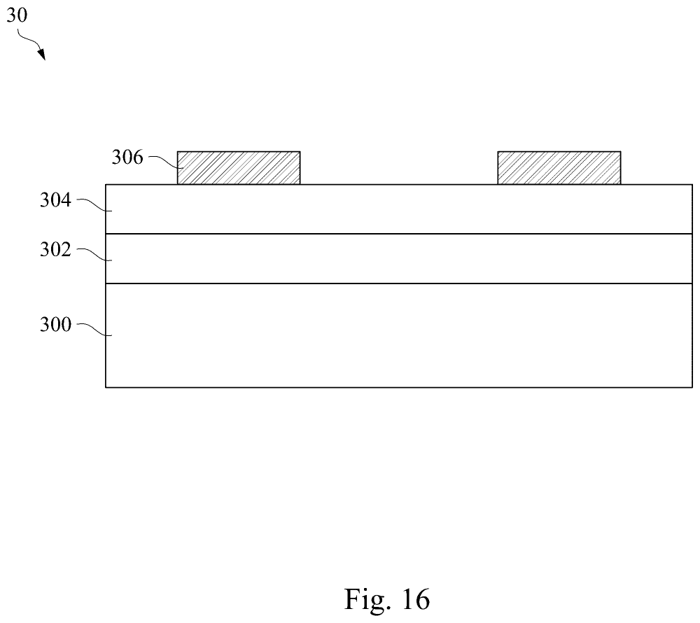

FIGS. 16-19 are cross-sectional views of a semiconductor device 30 in various stages of fabrication in accordance with some embodiments of the present disclosure. Reference is made to FIG. 16. In some embodiments, a dielectric layer 302 and a metal layer 304 are formed over a substrate 300 in sequence. In some embodiments, before forming the dielectric layer 302, a clean process is performed to the substrate 300, as discussed previously with regard to FIG. 1. The dielectric layer 302 and the metal layer 304 are similar to the dielectric layer 202 and the metal layer 204 with regard to FIG. 1 in terms of composition and formation method thereof, and thus the description thereof is omitted herein.

In FIG. 16, a mask layer 306 is formed over the metal layer 304 and then patterned to expose the metal layer 304. The mask layer 306 is similar to the mask layer 206 as discussed previously with regard to FIG. 9, and thus the description thereof is omitted herein.

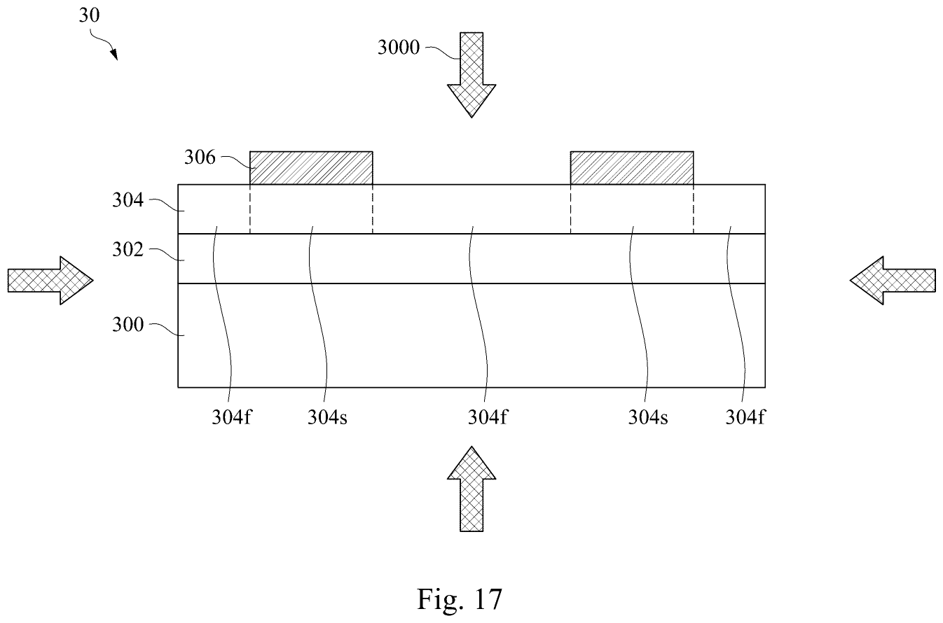

Reference is made to FIG. 17. In some embodiments, a pre-treatment process 3000 is performed to the metal layer 304 to control a phase of a subsequently formed 2D material layer. For example, the pre-treatment process 3000 is similar to the pre-treatment process 1000 as discussed previously with regard to FIG. 5, and thus the description thereof is omitted herein. Since the metal layer 304 has a first portion 304f exposed by the mask layer 306, during the pre-treatment process 3000, the first portion 304f is treated directly in the pre-treatment process 3000. The metal layer 304 has a second portion 304s covered by the mask layer 306, and thus the second portion can be referred to as being treated indirectly during the pre-treatment process 3000. Due to the first portion 304f being treated directly and the second portion 304s being treated indirectly in the pre-treatment process 3000, the first portion 304f and second portion 304s would turn into different phases in a subsequent tellurization process, which will be discussed in greater detail below. In some embodiments, the pre-treatment process 3000 is a high pressure annealing (HPA) process performed using oxygen, nitrogen, or a combination thereof. Details of the pre-treatment process 3000 is similar to the pre-treatment process 1000 as discussed previously with regard to FIG. 5, and thus the description thereof is omitted herein.

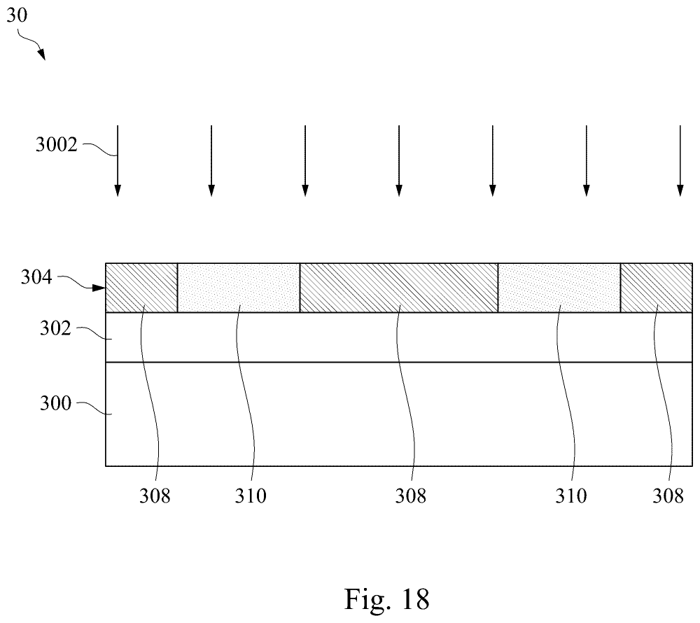

The mask layer 306 is then removed using, for example, an ashing process. Reference is made to FIG. 18. In some embodiments, a tellurization process 3002 is performed to the metal layer 304 using suitable methods, such as suing CVD. Details of the tellurization process 3002 is similar to the tellurization process 1002 as discussed previously with regard to FIG. 6A, and thus the description thereof is omitted herein. During the tellurization process 3002, the first portion 304f of the metal layer 304 forms a first Te-containing layer 308 with a semiconductor phase while the second portion of the metal layer 304 forms a second Te-containing layer 310 with a semimetal phase. For example, the first Te-containing layer 308 include MoTe₂ with 2H phase (hexagonal structure), which is a semiconductor phase, and the second portion 304s of the second Te-containing layer 310 include MoTe₂ with 1T′ phase (distorted octahedral structure), which is a semimetal phase. The first Te-containing layer 308 and the second Te-containing layer 310 form an MoTe₂ heterophase junction after the tellurization process 3002.

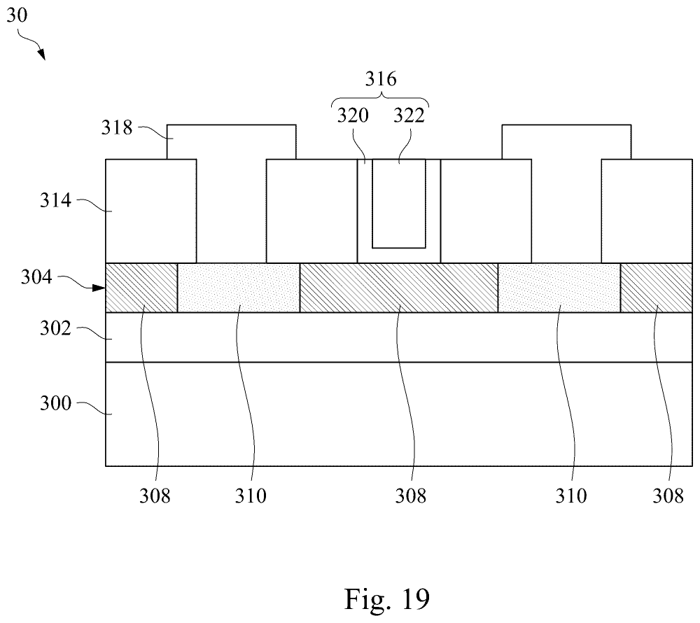

Reference is made to FIG. 19. An interlayer dielectric (ILD) layer 314 is formed over the first Te-containing layer 308 and the second Te-containing layer 310. A gate structure 316 and a conductive material 318 are then formed in the ILD layer 314. The ILD layer 314, the gate structure 316 and the conductive material 318 are similar to the ILD layer 216, the gate structure 222 and the conductive material 228 in terms of composition and formation method thereof, and thus the description thereof is omitted herein. The gate structure 316 may be a high-k/metal gate (HKMG) stack, however, other compositions are possible. In various embodiments, the gate structure 316 includes a high-k gate dielectric layer 320 and a gate electrode layer 322 formed over the high-k gate dielectric layer 320.

The semiconductor device 30 can include additional layers, not shown in FIG. 19. For example, additional back-end-of-line (BEOL) layers, middle-of-line (MOL) layers can be formed over the gate structure 316. By way of example and not limitation, an MOL layer can include a network of contacts that connect transistors and capacitor structures in front end of line (FEOL) to the structures in the BEOL layers.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that by using the high pressure annealing (HPA) process to treat a top portion of the 2D material layer directly and treat a bottom portion of the 2D material layer indirectly, the top portion and the bottom portion can turn into different phases in a subsequent tellurization process. Another advantage is that by forming the source/drain contact layers over the metal layer and performing the HPA process to treat the first portion exposed by the source/drain contact layers directly and the second portion covered by the source/drain contact layers indirectly, the first portion and the second portion of the metal layer would turn into different phases in a subsequent tellurization process. Yet another advantage is that by capping the metal layer with a mask layer and performing the HPA process to treat the first portion exposed by the mask layer directly and the second portion covered by the mask layer indirectly, the first portion and the second portion of the metal layer would turn into different phases in a subsequent tellurization process. The portion of the 2D material layer or metal layer treated directly by the HPA process would form a first Te-containing layer with a semiconductor phase and can serve as the channel of the transistor. The portion of the 2D material layer or metal layer treated indirectly by the HPA process would form a second Te-containing layer with a semimetal phase and can form the Ohmic contact with source/drain contact layers without a destructive process, a quality of the 2D material channel (i.e., the first Te-containing layer) can thus be maintained.

In some embodiments, a method of forming a semiconductor device comprises the following steps. A dielectric layer is formed over a substrate. Source/drain contact layers are formed in the dielectric layer. A 2D material layer is formed over the dielectric layer and the source/drain contact layers. An annealing process is performed to the 2D material layer. After performing the annealing process, a tellurization process is performed to the 2D material layer. A gate structure is formed over the 2D material layer. In some embodiments, the 2D material layer is a transition metal oxide layer. In some embodiments, after performing the tellurization process to the 2D material layer, the 2D material layer has a first Te-containing layer and a second Te-containing layer under the first Te-containing layer, the first Te-containing layer and the second Te-containing layer have different crystal phases. In some embodiments, the first Te-containing layer has a 2H phase. In some embodiments, the second Te-containing layer has a 1T′ phase. In some embodiments, the second Te-containing layer is between the first Te-containing layer and one of the source/drain contact layers. In some embodiments, the annealing process is performed using oxygen, nitrogen, or a combination thereof.

In some embodiments, a method of forming a semiconductor device comprises the following steps. A dielectric layer is formed over a substrate. A metal layer is formed over the dielectric layer. A patterned layer is formed over the metal layer to expose a first portion of the metal layer and cover a second portion of the metal layer. An annealing process is performed to the metal layer and the patterned layer. After performing the annealing process, a tellurization process is performed to the metal layer and the patterned layer. A gate structure is formed over the metal layer. In some embodiments, after performing the tellurization process to the metal layer, the metal layer has a first Te-containing layer and a second Te-containing layer under the patterned layer, and the first Te-containing layer and the second Te-containing layer have different crystal phases. In some embodiments, the first Te-containing layer has a 2H phase. In some embodiments, the second Te-containing layer has a 1T′ phase. In some embodiments, after performing the tellurization process to the metal layer, the metal layer has a metal portion under the patterned layer, and the metal portion is free from Te. In some embodiments, the second Te-containing layer has two Te-containing portions laterally separated from each other, and the metal portion of the metal layer is between the two Te-containing portions. In some embodiments, the patterned layer is a photoresist layer. In some embodiments, the patterned layer is a source/drain contact layer. In some embodiments, forming the patterned layer over the metal layer to expose the first portion of the metal layer and cover the second portion of the metal layer comprises forming a photoresist layer over the metal layer, patterning the photoresist layer, forming a source/drain contact layer over the resist layer and the metal layer, and lifting off the photoresist layer to partially remove the source/drain contact layer. In some embodiments, the annealing process is performed using oxygen, nitrogen, or a combination thereof.

In some embodiments, a semiconductor device comprises a substrate, a dielectric layer, a first Te-containing layer and a second Te-containing layer. The dielectric layer is over the substrate. The first Te-containing layer is over the dielectric layer. The second Te-containing layer is over the dielectric layer and having a phase different from a phase of the first Te-containing layer, wherein the second Te-containing layer has two Te-containing portions laterally separated from each other, the first Te-containing layer is between the two Te-containing portions of the second Te-containing layer. In some embodiments, the first Te-containing layer has a 2H phase, and the second Te-containing layer has a 1T′ phase. In some embodiments, the semiconductor device further comprises source/drain contact layers below the second Te-containing layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming a dielectric layer over a substrate;
forming source/drain contact layers in the dielectric layer;
forming a 2D material layer over the dielectric layer and the source/drain contact layers;
performing an annealing process to the 2D material layer;
after performing the annealing process, performing a tellurization process to the 2D material layer; and
forming a gate structure over the 2D material layer.

2. The method of claim 1, wherein the 2D material layer is a transition metal oxide layer.

3. The method of claim 1, wherein after performing the tellurization process to the 2D material layer, the 2D material layer has a first Te-containing layer and a second Te-containing layer under the first Te-containing layer, the first Te-containing layer and the second Te-containing layer have different crystal phases.

4. The method of claim 3, wherein the first Te-containing layer has a 2H phase.

5. The method of claim 3, wherein the second Te-containing layer has a 1T′ phase.

6. The method of claim 3, wherein the second Te-containing layer is between the first Te-containing layer and one of the source/drain contact layers.

7. The method of claim 1, wherein the annealing process is performed using oxygen, nitrogen, or a combination thereof.

8. A method of forming a semiconductor device, comprising:
forming a dielectric layer over a substrate;
forming a metal layer over the dielectric layer;
forming a patterned layer over the metal layer to expose a first portion of the metal layer and cover a second portion of the metal layer;
performing an annealing process to the metal layer and the patterned layer;
after performing the annealing process, performing a tellurization process to the metal layer and the patterned layer; and
forming a gate structure over the metal layer.

9. The method of claim 8, wherein after performing the tellurization process to the metal layer, the metal layer has a first Te-containing layer and a second Te-containing layer under the patterned layer, and the first Te-containing layer and the second Te-containing layer have different crystal phases.

10. The method of claim 9, wherein the first Te-containing layer has a 2H phase.

11. The method of claim 9, wherein the second Te-containing layer has a 1T′ phase.

12. The method of claim 9, wherein after performing the tellurization process to the metal layer, the metal layer has a metal portion under the patterned layer, and the metal portion is free from Te.

13. The method of claim 12, wherein the second Te-containing layer has two Te-containing portions laterally separated from each other, and the metal portion of the metal layer is between the two Te-containing portions.

14. The method of claim 8, wherein the patterned layer is a photoresist layer.

15. The method of claim 8, wherein the patterned layer is a source/drain contact layer.

16. The method of claim 8, wherein forming the patterned layer over the metal layer to expose the first portion of the metal layer and cover the second portion of the metal layer comprises:
forming a photoresist layer over the metal layer;
patterning the photoresist layer;
forming a source/drain contact layer over the resist layer and the metal layer; and
lifting off the photoresist layer to partially remove the source/drain contact layer.

17. The method of claim 8, wherein the annealing process is performed using oxygen, nitrogen, or a combination thereof.

18. A semiconductor device, comprising:
a substrate;
a dielectric layer over the substrate;
a first Te-containing layer over the dielectric layer; and
a second Te-containing layer over the dielectric layer and having a phase different from a phase of the first Te-containing layer, wherein the second Te-containing layer has two Te-containing portions laterally separated from each other, the first Te-containing layer is between the two Te-containing portions of the second Te-containing layer.

19. The semiconductor device of claim 18, wherein the first Te-containing layer has a 2H phase, and the second Te-containing layer has a 1T′ phase.

20. The semiconductor device of claim 19, further comprising:
source/drain contact layers below the second Te-containing layer.
